(19) United States
(12) Patent Application Publication
(10) Pub. No.: US 2026/0305295 A1
(43) Pub. Date: Oct. 1, 2026

(54) CONDUCTIVE VIAS FOR REDISTRIBUTION LINES IN SEMICONDUCTOR DEVICES

(71) Applicants: Taiwan Semiconductor Manufacturing Company, Ltd., Hsinchu (TW); TSMC Arizona Corporation, Phoenix, AZ (US)

(72) Inventors: Xuewen TANG, Gilbert, AZ (US); Wen-Hsien CHUANG, Taipei City (TW); Hao Chun LIU, Hsinchu (TW); Hsiang-Ku SHEN, Hsinchu City (TW); Chen-Chiu HUANG, Taichung City (TW)

(73) Assignees: Taiwan Semiconductor Manufacturing Company, Ltd., Hsinchu (TW); TSMC Arizona Corporation, Phoenix, AZ (US)

(21) Appl. No.: 19/094,416

(22) Filed: Mar. 28, 2025

(51) Int. Cl. H01L 23/522; H01L 21/768; H01L 23/528

(52) U.S. Cl. CPC H10W 20/42; H10W 20/035; H10W 20/043; H10W 20/435; H10W 20/081

(57) ABSTRACT

This disclosure is directed to a structure having a conductive via connecting an RDL and an interconnect structure and a method of forming the structure. The structure can include a conductive line in a substrate and a dielectric layer on the conductive line. The structure can further include the conductive via through the dielectric layer and in contact with the conductive line. The conductive via can include a first barrier layer on a side surface of the dielectric layer, a seed layer on the barrier layer, and a conductive layer surrounded by the seed layer. Top surfaces of the conductive via and the dielectric layer can be substantially coplanar. The structure can further include a second barrier layer on the conductive via and the dielectric layer and a redistribution line (RDL) on the second barrier layer. The RDL can have a substantially even top surface free from irregular concave shapes.

### BACKGROUND

The semiconductor integrated circuit (IC) industry has experienced exponential growth. Technological advances in IC materials and design have produced generations of ICs, where each generation has smaller and more complex circuits than the previous generation. In the course of IC evolution, there has been increasing demand for higher storage capacity, faster processing systems, higher performance, and lower costs. To meet these demands, functional density (e.g., the number of interconnected devices per chip area) has generally increased while geometry size (e.g., the smallest component or line that can be created using a fabrication process) has decreased. Accordingly, critical dimensions of redistribution structures of ICs coupling the interconnected devices to external circuits are shrinking to facilitate connecting more devices within a limited space.

### BRIEF DESCRIPTION OF THE DRAWINGS

Aspects of the present disclosure are best understood from the following detailed description when read with the accompanying figures. It is noted that, in accordance with the common practice in the industry, various features are not drawn to scale. In fact, the dimensions of the various features may be arbitrarily increased or reduced for clarity of illustration and discussion.

FIG. 1 is a cross-sectional view of a semiconductor device including conductive vias connecting redistribution lines (RDLs) and interconnect structures, in accordance with some embodiments.

FIG. 2 is a cross-sectional view of a zoomed-in region of FIG. 1, in accordance with some embodiments.

FIG. 3 is a flowchart of a method of forming a semiconductor device including conductive vias connecting RDLs and interconnect structures, in accordance with some embodiments.

FIGS. 4-12 are cross-sectional views of intermediate structures during the fabrication of conductive vias connecting RDLs and interconnect structures, in accordance with some embodiments.

Illustrative embodiments will now be described with reference to the accompanying drawings. In the drawings, like reference numerals generally indicate identical, functionally similar, and/or structurally similar elements.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over a second feature in the description that follows may include embodiments in which the first and second features are formed in direct contact, and may also include embodiments in which additional features may be formed that are between the first and second features, such that the first and second features are not in direct contact. As used herein, the formation of a first feature on a second feature means the first feature is formed in direct contact with the second feature. In addition, the present disclosure may repeat reference numerals and/or letters in the various examples. This repetition does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In some embodiments, the terms “about” and “substantially” can indicate a value of a given quantity that varies within 5% of the value (e.g., ±1%, ±2%, ±3%, ±4%, ±5% of the value). These values are merely examples and are not intended to be limiting. It is to be understood that the terms “about” and “substantially” can refer to a percentage of the values as interpreted by those skilled in relevant art(s) in light of the teachings herein.

It is noted that references in the specification to “one embodiment,” “an embodiment,” “an example embodiment,” “exemplary,” etc., indicate that the embodiment described may include a particular feature, structure, or characteristic, but every embodiment may not necessarily include the particular feature, structure, or characteristic. Moreover, such phrases do not necessarily refer to the same embodiment. Further, when a particular feature, structure or characteristic is described in connection with an embodiment, it would be within the knowledge of one skilled in the art to effect such feature, structure or characteristic in connection with other embodiments whether or not explicitly described.

It is to be understood that the phraseology or terminology herein is for the purpose of description and not of limitation, such that the terminology or phraseology of the present specification is to be interpreted by those skilled in relevant art(s) in light of the teachings herein.

An integrated circuit includes multiple semiconductor devices that are electrically connected together by interconnect structures. The interconnect structures include, for example, multiple layers of metal lines embedded in dielectric materials and provide routing between the semiconductor devices. The interconnect structures can electrically couple to redistribution lines (RDLs), which include a layer of conductive lines in contact with conductive pads that provide the integrated circuit external electrical connections to other circuits or devices. The RDLs and the interconnect structures can be electrically connected by conductive vias that extend vertically through dielectric layers between the metal lines of the interconnect structures and the RDLs. The conductive vias and the RDLs can be formed by etching the dielectric materials on the interconnect structures to form openings through the dielectric materials, followed by depositing a conductive material (e.g., aluminum) in the openings and on the dielectric materials. Barrier layers can be formed on side surfaces of the conductive vias and the bottom surface of the RDLs to avoid diffusion or migration of conductive materials from the conductive vias and the RDLs into surrounding dielectric layers.

As semiconductor devices continue scaling down, critical dimensions of the conductive vias are shrinking to facilitate connecting more semiconductor devices within a limited space. Accordingly, it is more demanding and challenging to form RDLs that can meet electrical and mechanical requirements of scaled-down semiconductor devices. For example, in the above-mentioned formation process of the conductive vias and the RDLs, top surfaces of the RDLs can be uneven or irregular and have a concave shape directly above the conductive vias. This is because the deposition of the conductive material forms a conformal layer on exposed surfaces of the dielectric materials, and by filling the conductive vias, the RDLs can have a thickness at locations directly above the conductive vias less than a thickness at locations away from the conductive vias. The concave shape can introduce defects in structures subsequently formed on such irregular top surfaces of the RDLs and can cause further issues that impact the electrical and mechanical stability and reliability of the integrated circuit. For example, passivation layers conformally formed on the RDLs can have voids and seams and may introduce internal stress in surrounding regions, resulting in cracking of the structure during thermal cycling and compromising the quality of the integrated circuit. With the scaling down of the critical dimensions of the conductive vias and the RDLs, the drawback can become more crucial as the RDLs and their surrounding structures become more sensitive to the irregular top surfaces of the RDLs, which can pose significant limitations to the scaling down of the semiconductor devices.

To overcome the above-mentioned challenges, the embodiments described herein are directed to a structure including a conductive via connecting an RDL and an interconnect structure and a method of forming the structure. In some embodiments, the structure can include a conductive line on a substrate and a dielectric layer on the conductive line. The structure can further include a conductive via through the dielectric layer and in contact with the conductive line. The conductive via can include a first barrier layer on a side surface of the dielectric layer, a seed layer on the barrier layer, and a conductive layer surrounded by the seed layer. Top surfaces of the conductive via and the dielectric layer can be substantially coplanar. The structure can further include a second barrier layer on the conductive via and the dielectric layer and a redistribution line (RDL) on the second barrier layer. Because the top surfaces of the conductive via and the dielectric layer are substantially coplanar, the RDL can have substantially even top surface without having irregular concave shapes. In some embodiments, the method can include forming a conductive line on a substrate and a dielectric layer on the conductive line. The method can further include etching an opening in the dielectric layer to expose the conductive line, depositing a first barrier layer on side surfaces of the opening, and depositing a seed layer on the first barrier layer. The method can further include depositing a first metal in the opening to form a conductive via having a top surface substantially coplanar with a top surface of the dielectric layer. The method can further include depositing a second barrier layer on the top surfaces of the conductive via and the dielectric layer and depositing a second metal on the second barrier layer to form an RDL. The first and second metals can be different. In particular, the first metal can have a thermal expansion coefficient closer to that of the dielectric layer than that of the second metal.

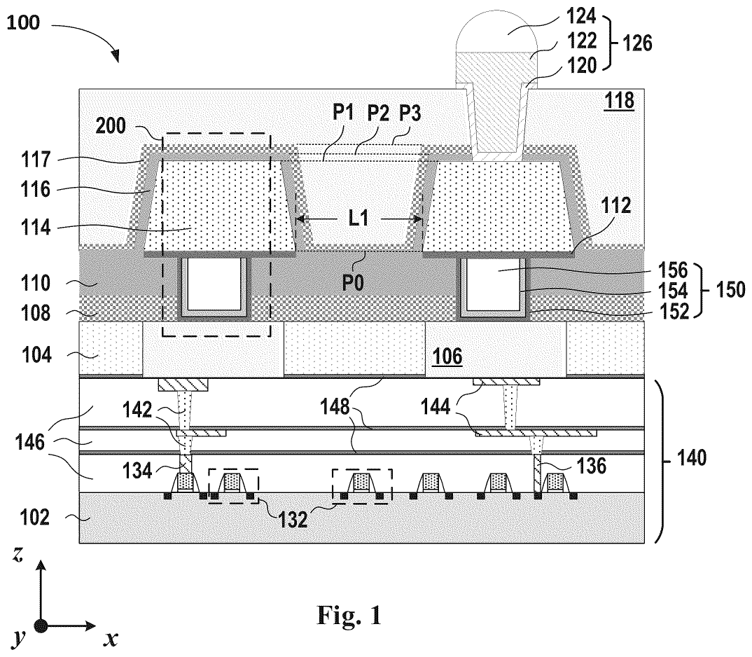

A semiconductor device 100 is shown with a cross-sectional view in FIG. 1, according to some embodiments. Semiconductor device 100 can be included in a microprocessor, memory cell, or other integrated circuit (IC). Semiconductor device 100 can include a semiconductor substrate 102, transistors 132 disposed on semiconductor substrate 102, and a number of interconnect structures disposed on transistors 132 and including metal vias 142 and metal lines 144. Semiconductor device 100 can further include conductive lines 106 electrically coupled to metal vias 142 and metal lines 144. Semiconductor device 100 can further include redistribution structures electrically coupled to conductive liens 106 and including conductive vias 150 and redistribution lines (RDLs) 114. Semiconductor device 100 can further include contact structure 126 in contact with RDLs 114 to provide electrical contact of semiconductor device 100 to external circuits.

Referring to FIG. 1, semiconductor substrate 102 can be a semiconductor material, such as silicon. In some embodiments, semiconductor substrate 102 can include a crystalline silicon substrate (e.g., wafer). In some embodiments, semiconductor substrate 102 can include (i) an elementary semiconductor, such as silicon (Si) or germanium (Ge); (ii) a compound semiconductor including silicon carbide (SiC), gallium arsenide (GaAs), gallium phosphide (GaP), indium phosphide (InP), indium arsenide (InAs), and/or indium antimonide (InSb); (iii) an alloy semiconductor including silicon germanium carbide (SiGeC), silicon germanium (SiGe), gallium arsenic phosphide (GaAsP), gallium indium phosphide (InGaP), gallium indium arsenide (InGaAs), gallium indium arsenic phosphide (InGaAsP), aluminum indium arsenide (InAlAs), and/or aluminum gallium arsenide (AlGaAs); or (iv) a combination thereof. Further, semiconductor substrate 102 can be doped depending on design requirements (e.g., p-type substrate or n-type substrate). In some embodiments, semiconductor substrate 102 can be doped with p-type dopants (e.g., boron (B), indium (In), aluminum (Al), or gallium (Ga)) or n-type dopants (e.g., phosphorus (P), arsenic (As), or antimony (Sb)). In some embodiments, a crystal orientation of semiconductor substrate 102 can be (100), (110), or (111).

Referring to FIG. 1, transistors 132 disposed on semiconductor substrate 102 can include metal oxide semiconductor field effect transistors (MOSFETs), such as planar MOSFETS, fin field effect transistors (FinFETs), complementary fin field effect transistors (CFETs), gate-all-around field effect transistors (GAA FETs), and/or vertical fin field effect transistors (VFETs). Transistors 132 can be embedded in a dielectric layer 146. Transistors 132 can be electrically coupled to the interconnect structures (e.g., metal vias 142 and metal lines 144) by contact structures, such as gate contacts 134 and source/drain contacts 136.

Referring to FIG. 1, the interconnect structures disposed on transistors 132 can include multiple interconnect layers. Although there are two interconnect layers shown in FIG. 1 as an example, the number of the interconnect layers can be any positive integer number. For example, semiconductor device 100 can include 2, 4, 8, 12, 16, 24, or 32 interconnect layers. In some embodiments, the interconnect layers can be formed in a back-end-of-line (BEOL) process. Each interconnect layer can include an etch stop layer 148 and a dielectric layer 146. Each interconnect layer can further include metal lines 144 in dielectric layer 146 and metal vias 142 through etch stop layer 148 and dielectric layer 146. Metal lines 144 can extend in horizontal directions (e.g., along the x or y axes). Metal vias 142 can extend in a vertical direction (e.g., along the z axis). Metal vias 142 can electrically couple metal lines 144 below and/or above each interconnect layer. Metal lines 144 and metal vias 142 can include any suitable conductive materials, such as titanium, aluminum, copper, tungsten, tantalum, nickel, ruthenium, other suitable metals, and/or a combination thereof. Etch stop layers 148 and dielectric layers 146 can include low-k dielectric materials, such as silicon oxide (SiₓO_{y}), silicon nitride (SiₓN_{y}), silicon oxy-carbon-nitride (SiₓO_{y}C_{z}Nᵤ), silicon carbon-nitride (SiₓC_{y}N_{z}), silicon oxy-nitride (SiₓO_{y}N_{z}), silicon carbide (SiₓC_{y}), aluminum nitride (AlₓN_{y}), aluminum oxide (AlₓO_{y}), or aluminum oxy-nitride (AlₓO_{y}N_{z}).

Referring to FIG. 1, conductive lines 106 can be formed on a top most dielectric layer 146 and in contact with top most metal vias 142 and/or metal lines 144. Conductive lines 106 can be embedded in a dielectric layer 104 and can extend in the horizontal directions (e.g., along the x or y axes). Although there is one layer of conductive lines shown in FIG. 1 as an example, semiconductor device 100 can include additional layers of conductive lines 106. Conductive lines 106 can include a suitable conductive material, such as tungsten (W), titanium (Ti), silver (Ag), ruthenium (Ru), copper (Cu), cobalt (Co), Al, iridium (Ir), nickel (Ni), molybdenum (Mo), metal alloys, and a combination thereof.

Referring to FIG. 1, dielectric layers 108 and 110 can be disposed on conductive lines 106 and dielectric layer 104. Dielectric layers 108 and 110 can include low-k dielectric materials such as SiₓO_{y}, SiₓN_{y}, SiₓO_{y}C_{z}Nᵤ, SiₓC_{y}N_{z}, SiₓO_{y}N_{z}, SiₓC_{y}, AlₓN_{y}, AlₓO_{y}, or AlₓO_{y}N_{z}. In some embodiments, dielectric layers 108 and 110 can include different dielectric materials. For example, dielectric layer 108 can include silicon nitride, and dielectric layer 110 can include silicon oxide, or vice versa.

Referring to FIG. 1, conductive vias 150 can be disposed through dielectric layers 108 and 110 and in contact with conductive lines 106. Each of conductive vias 150 can include a barrier layer 152, a seed layer 154 on barrier layer 152, and a conductive layer 156 on seed layer 154. Barrier layer 152 can be in contact with side surfaces of dielectric layers 108 and 110 and a top surface of conductive line 106. Barrier layer 152 can structurally isolate seed layer 154 and conductive layer 156 from the surrounding dielectric layers 108 and 110 to prevent materials of seed layer 154 and conductive layer 156 from diffusing or migrating into dielectric layers 108 and 110. Barrier layer 152 can enclose side surfaces and a bottom surface of seed layer 154. Seed layer 154 can enclose a bottom surface and side surfaces of conductive layer 156. In some embodiments, top surfaces of barrier layer 152, seed layer 154, and conductive layer 156 can be substantially coplanar. In some embodiments, the top surfaces of barrier layer 152, seed layer 154, and/or conductive layer 156 can be substantially coplanar with a top surface of dielectric layer 110.

Barrier layer 152 can include conductive materials such that conductive via 150 can electrically couple to conductive line 106. For example, barrier layer 152 can include tantalum nitride (TaN) and/or titanium (Ti). These conductive materials can also block materials of seed layer 154 and conductive layer 156 from diffusing or migrating into dielectric layers 108 and 110. Seed layer 154 can include a conductive material to provide a conductive surface for electrochemical deposition of conductive layer 156. In some embodiments, seed layer 154 and conductive layer 156 can include the same metallic material. For example, seed layer 154 and conductive layer 156 can include Cu. In some embodiments, seed layer 154 and conductive layer 156 can include different metallic materials. For example, seed layer 154 and conductive layer 156 can include Cu and Al, respectively. In some embodiments, Cu is preferred over Al for conductive layer 156 because (i) the electrical resistivity of Cu (1.68×10⁻⁸ Ω·m) is less than that of Al (2.65×10⁻⁸ Ω·m) and can provide better electrical conductivity between RDLs 114 and conductive line 106, (ii) the thermal conductivity of Cu (401 W/mK) is greater than that of Al (237 W/mK) and can provide better performance of heat dissipation, and (iii) the thermal expansion coefficient of Cu (17×10⁻⁶/° C.) is less than that of Al (23×10⁻⁶/° C.) and closer to those of the dielectric materials of surrounding dielectric layers 108 and 110 (for example, the thermal expansion coefficients of silicon oxide and silicon nitrides are 0.6×10⁻⁶/° C. and 3.2×10⁻⁶/° C., respectively) and can provide better mechanical robustness during thermal cycles.

In some embodiments, a thickness of barrier layer 152 can be between about 30 nm and about 100 nm. If the thickness of barrier layer 152 is less than about 30 nm, barrier layer 152 may not have sufficient uniformity and/or adequate coverage to effectively prevent the materials of seed layer 154 and conductive layer 156 from diffusing or migrating into dielectric layers 108 and 110. If the thickness of barrier layer 152 is greater than about 100 nm, portions of barrier layer 152 on side surfaces of dielectric layers 108 and 110 may be too thick to facilitate the scaling down of the critical dimension of conductive vias 150. In some embodiments, a thickness of seed layer 154 can be between about 30 nm and about 200 nm. If the thickness of seed layer 154 is less than about 30 nm, seed layer 154 may have a low conductivity that may compromise the efficiency of the electrochemical deposition of conductive layer 156. If the thickness of seed layer 154 is greater than about 100 nm, portions of seed layer 154 on side surfaces of barrier layer 152 may be too thick to facilitate the scaling down of the critical dimension of conductive vias 150. In some embodiments, a thickness of conductive layer 156 can be between about 0.3 μm and about 2 μm. In some embodiments, a horizontal critical dimension (e.g., a width along a horizontal direction along the x or y axes) of conductive layer 156 can be between about 0.5 μm and about 2 μm.

Referring to FIG. 1, barrier layers 112 can be disposed on top surfaces of conductive via 150 and dielectric layer 110, and RDLs 114 can be disposed on barrier layers 112. In some embodiments, RDLs 114 can include a conductive material, such as Al and/or Cu. In some embodiments, RDLs 114 and conductive layer 156 can include different conductive materials. For example, RDLs 114 can include Al, and conductive layer 156 can include Cu. In some embodiments, barrier layer 112 can include TaN and/or Ti to prevent the conductive material of RDLs 114 from diffusing into dielectric layer 110. In some embodiments, barrier layer 112 can include the same material as barrier layer 152. In some embodiments, barrier layers 112 and 152 can include different materials. For example, barrier layer 152 can include TaN and barrier layer 112 can include Ti, or vice versa.

Referring to FIG. 1, passivation layers 116 and 117 can be disposed over top and side surfaces of RDLs 114. In some embodiments, portions of passivation layers 116 and 117 can be disposed between RDLs 114. In some embodiments, passivation layer 116 can be in contact with dielectric layer 110. Passivation layers 116 and 117 can include low-k dielectric materials, such as SiₓO_{y}, SiₓN_{y}, SiₓO_{y}C_{z}Nᵤ, SiₓC_{y}N_{z}, SiₓO_{y}N_{z}, SiₓC_{y}, AlₓN_{y}, AlₓO_{y}, or AlₓO_{y}N_{z}. In some embodiments, passivation layers 116 and 117 can include different dielectric materials. For example, passivation layer 117 can include silicon nitride and passivation layer 116 can include silicon oxide, or vice versa. In some embodiments, passivation layer 116 and dielectric layer 110 can include the same dielectric material. For example, passivation layer 116 and dielectric layer 110 can both include silicon oxide or silicon nitride.

Referring to FIG. 1, in some embodiments, because of the presence of the coplanar top surfaces of conductive via 150 and dielectric layer 110, an interface between an RDL 114 and a barrier layer 112 can be coplanar with another interface between an adjacent RDL 114 and another barrier layer 112, as indicated by dashed line P0. For the same reason, top surfaces of these two adjacent RDLs 114 can be flat and coplanar with each other, as indicated by dashed line P1. For the same reason, horizontal interfaces between passivation layers 116 and 117 on these two adjacent RDLs 114 can be flat and coplanar with each other, as indicated by dashed line P2. For the same reason, horizontal top surfaces of passivation layer 117 on these two adjacent RDLs 114 can be flat and coplanar with each other, as indicated by dashed line P3.

Referring to FIG. 1, a distance between adjacent RDLs 114 can be greater than a minimal distance L1, which can be between about 0.5 um and about 2 um. For example, the minimal distance L1 can be about 1 um. In some embodiments, the substantially even top surfaces of RDLs 114 can provide reliable thermal and mechanical properties of structures (e.g., passivation layers 116 and 117) formed over RDLs 114, such that the minimal distance L1 can be about 1 um or about 0.5 um. In some embodiments, if the minimal distance L1 is less than 1 um or about 0.5 um, passivation layers 116 and 117 deposited between adjacent RDLs 114 may not have sufficient space to be form as defect-free layers. In some embodiments, without conductive via 150, RDLs formed through dielectric layers 108 and 110 and having direct contacts with conductive lines 106 may have irregular top surface with concave structures directly above the direct contacts. Structures subsequently formed over such RDLs may have compromised thermal and mechanical properties due to the internal stress induced by their irregular interface with the RDLs. As a result, in order to maintain the thermal and mechanical reliability of these structures, the minimal distance between adjacent RDLs cannot be below about 1 μm.

In some embodiments, conductive via 150 can include Cu as the conductive material, which can provide better thermal and mechanical properties for passivation layer 116 and dielectric layers 108 and 110, compared with Al as the conductive material. For example, a fracture mechanical test shows that a silicon oxide layer formed near a Cu layer can have a normal stress of about 450 MPa. In comparison, a silicon oxide layer formed near an Al layer can have a greater normal stress of about 550 MPa. Using Cu instead of Al as the conductive material for conductive via 150 can reduce the normal stress in passivation layer 116 and dielectric layers 108 and 110 and improve their thermal and mechanical properties.

Referring to FIG. 1, a polyimide layer 118 can be disposed over passivation layer 117 and include a polyimide. In some embodiments, a portion of polyimide layer 118 can be disposed between adjacent RDLs 114.

Referring to FIG. 1, contact structure 126 can be disposed on RDL 114 to provide electrical contact of semiconductor device 100 to external devices or circuits. Contact structure 126 can include an under-bump metallization (UBM) 120, a metal bump 122, and a solder 124. UBM 120 can include a conductive material similar to that of conductive line 106 and/or RDL 114. In some embodiments, UBM 120 can include Al, Ti, Cu, or Ti/Cu alloy. UBM 120 can be formed on polyimide layer 118 and through passivation layers 117 and 116. A portion of UBM 120 can be in contact with a top surface of RDL 114. UBM 120 is electrically coupled to conductive line 106 by conductive via 150 and RDL 114. In some embodiments, an interface between RDL 114 and UBM 120 can be disposed directly above conductive via 150 and dielectric layer 110 and can be flat and parallel to the top surface of conductive line 106. UBM 120 can improve adhesion of metal bump 122, thus improving uniformity of forming metal bumps across a wafer in bumping processes. Metal bump 122 can be formed on UBM 120. Metal bump 122 can include a conductive material similar to that of conductive line 106, RDL 114, and/or UBM 120. In some embodiments, metal bump 122 can include Al or Cu. In some embodiments, there can be between about 7000 and about 40000 metal bumps 122 on a wafer. Solder 124 can include a soldering material, such as tin (Sn). Solder 124 can be formed on metal bump 122.

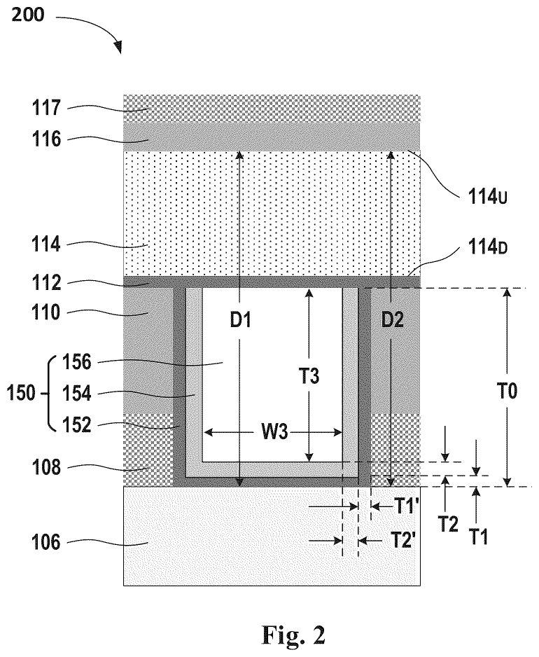

FIG. 2 illustrates a cross-sectional view of a structure 200, which is a zoomed-in portion of FIG. 1 around a region including a conductive line 106, a conductive via 150, and an RDL 114 electrically coupled with each other. The discussion of elements in FIG. 1 with the same annotations applies to FIG. 2, unless mentioned otherwise.

Referring to FIG. 2, in some embodiments, a total thickness T0 of dielectric layers 108 and 110 can be between about 0.3 μm and about 1 μm. In some embodiments, a thickness T1 of a horizontal portion of barrier layer 152 can be between about 30 nm and about 100 nm. In some embodiments, a thickness T1′ of a vertical portion of barrier layer 152 can be between about 30 nm and about 100 nm. In some embodiments, thicknesses T1 and T1′ can be substantially the same. In some embodiments, thicknesses T1 and T1′ can be different. For example, thickness T1 can be greater than thickness T1′, or vice versa. In some embodiments, a thickness T2 of a horizontal portion of seed layer 154 can be between about 30 nm and about 200 nm. In some embodiments, a thickness T2′ of a vertical portion of seed layer 154 can be between about 30 nm and about 200 nm. In some embodiments, thicknesses T2 and T2′ can be substantially the same. In some embodiments, thicknesses T2 and T2′ can be different. For example, thickness T2 can be greater than thickness T2′, or vice versa. In some embodiments, thicknesses T2 and T2′ can be greater than thicknesses T1 and T1′. In some embodiments, a thickness T3 of conductive layer 156 can be between about 0.3 μm and about 2 μm. In some embodiments, a horizontal width W3 of conductive layer 156 can be between about 0.5 μm and about 2 μm.

Referring to FIG. 2, in some embodiments, the top surfaces of conductive via 150 and dielectric layer 110 can be substantially coplanar, such that a total thickness T of conductive via 150 defined as T=T1+T2+T3 can be substantially the same as a thickness T0 of dielectric layer 110. In particular, the top surfaces of conductive layer 156, seed layer 154, barrier layer 152, and dielectric layer 110 can be substantially coplanar. In some embodiments, a difference between thickness T and thickness T0 can be less than a maximal variance ΔT (i.e., |T−T0|<ΔT). In some embodiments, the maximal variance ΔT can be between about 0.01 μm and about 0.3 μm. For example, the maximal variance ΔT can be between about 0.01 μm and about 0.1 μm. If the maximal variance ΔT is greater than about 0.3 μm, the difference between thickness T and thickness T0 can be too large, resulting in irregular top surfaces of RDL 114 subsequently formed on conductive via 150 and dielectric layer 110. By controlling and minimizing the difference between thickness T and thickness T0, the top surfaces of conductive via 150 and dielectric layer 110 can be substantially coplanar, and structures subsequently formed above these top surfaces can have smooth and even surfaces substantially parallel to these top surfaces. For example, an interface 114D between RDL 114 and barrier layer 112 can have a smooth and substantially even region directly above conductive via 150 and dielectric layer 110. Interface 114D can be substantially parallel to the top surfaces of conductive via 150 and dielectric layer 110. A variation of interface 114D in a vertical direction (e.g., along the z-axis) can be less than the maximal variance ΔT. In some embodiments, an top surface 114U of RDL 114 can be smooth and substantially even across a region directly above conductive via 150 and dielectric layer 110. Top surface 114U can be substantially parallel to the top surfaces of conductive via 150 and dielectric layer 110. A variation of interface 114D in a vertical direction (e.g., along the z-axis) can be less than the maximal variance ΔT. In some embodiments, because barrier layer 112 and RDL 114 can be formed on coplanar top surfaces of conductive via 150 and dielectric layer 110, top surface 114U can have a uniform vertical distance to conductive line 106. For example, top surface 114U can include a first portion directly above conductive via 150 and a second portion directly above dielectric layer 110, where a first vertical distance D1 between conductive line 106 and the first portion of top surface 114U is substantially the same as a second vertical distance D2 between conductive line 106 and the second portion of top surface 114U. In some embodiments, a difference between first and second vertical distances D1 and D2 can be less than the maximal variance ΔT. In some embodiments, because top surface 114U is uniform, substantially even, and concave-free, passivation layers 116 and 117 formed on top surface 114U can be uniform, substantially even, and concave-free across the first and second portions of top surface 114U. For example, an interface between passivation layers 116 and 117 across the first and second portions of top surface 114U can be parallel to the top surface of conductive line 106.

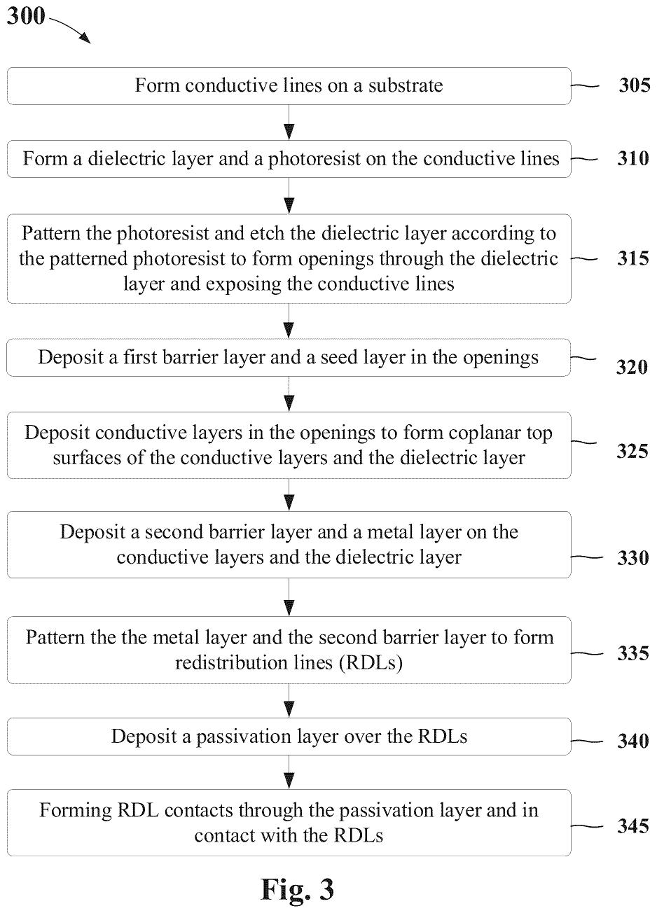

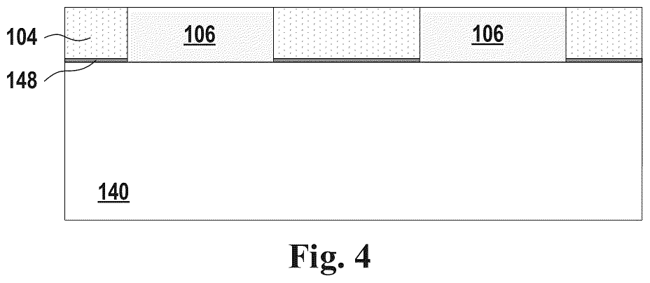

According to some embodiments, FIG. 3 illustrates a flowchart of a fabrication method 300 for the formation of semiconductor device 100 as shown in FIG. 1. This disclosure is not limited to this operational description and additional operations may be performed. Other fabrication operations can be performed between the various operations of method 300, and are omitted merely for clarity. Moreover, not all operations may be needed to perform the disclosure provided herein. Additionally, some of the operations may be performed simultaneously, or in a different order than the ones shown in FIG. 3. In some embodiments, one or more other operations may be performed in addition to or in place of the presently described operations. For illustrative purposes, method 300 is described with reference to the structures shown in FIGS. 1 and 4-12. The discussion of elements in FIGS. 1 and 2 with the same annotations applies to FIGS. 4-12, unless mentioned otherwise.

Referring to FIG. 3, method 300 can begin with operation 305 and the process of forming conductive lines on a substrate. In some embodiments, the substrate can be a substrate 140 including semiconductor substrate 102, transistors 132, gate contacts 134, source/drain contacts 136, metal lines 144, metal vias 142, dielectric layers 146, and etch stop layers 148, as shown in FIG. 1. In some embodiments, the conductive lines can include conductive lines 106 embedded in dielectric layer 104 and disposed on substrate 140, as described with reference to FIG. 4, in which the abovementioned details within substrate 140 are not shown for simplicity, except a topmost etch stop layer 148. In some embodiments, forming the conductive lines can include (i) depositing dielectric layer 104, (ii) forming openings through dielectric layer 104 and topmost etch stop layer 148, and (iii) depositing a conductive material in the openings to form conductive lines 106.

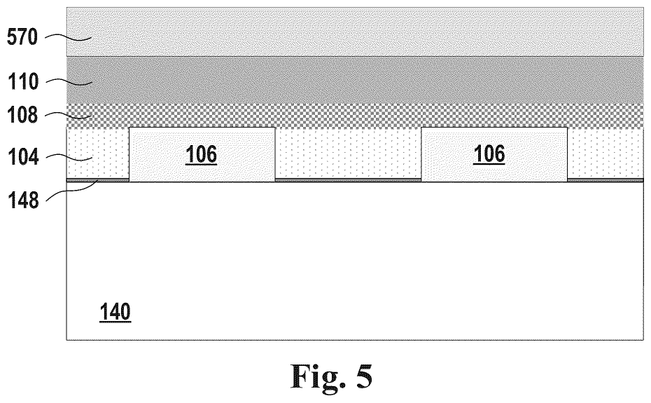

Referring to FIG. 3, method 300 can continue with operation 310 and the process of forming a dielectric layer and a photoresist on the conductive lines. For example, a dielectric layer including dielectric layers 108 and 110 can be deposited over conductive line 106 and dielectric layer 104, and a photoresist 570 can be deposited over dielectric layer 110, as described with reference to FIG. 5. In some embodiments, depositing dielectric layer 108 can include blanket depositing a layer of dielectric material, such as silicon nitride. In some embodiments, depositing dielectric layer 110 can include blanket depositing a layer of dielectric material different from that of dielectric layer 108, such as silicon oxide. In some embodiments, dielectric layers 108 and 110 can be deposited by a chemical vapor deposition (CVD) process, an atomic vapor deposition process (ALD), a plasma-enhanced CVD (PECVD) process, and/or a physical vapor deposition (PVD) process. In some embodiments, deposition parameters (e.g., the deposition time, the deposition rate, the pressure of the deposition chamber, the temperature of substrate 140, and/or the flowrates of the precursor gases) can be controlled during the deposition of dielectric layers 108 and 110 to control their thicknesses. In some embodiments, after the deposition of dielectric layer 110, photoresist 570 can be coated on dielectric layer 110. For example, photoresist 570 can be coated on dielectric layer 110 by a spin-on method.

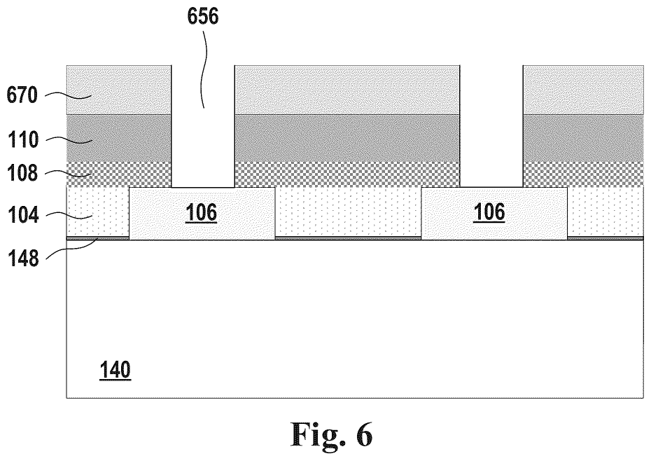

Referring to FIG. 3, method 300 can continue with operation 315 and the process of patterning the photoresist and etch the dielectric layer according to the patterned photoresist to form openings through the dielectric layer and exposing the conductive lines. For example, photoresist 570 in FIG. 5 can be patterned to form photoresist 670, as described with reference to FIG. 6, and dielectric layers 108 and 110 can be etched through according to photoresist 670 to form openings 656, which expose conductive lines 106. In some embodiments, etching dielectric layers 108 and 110 can include a dry etching process with etchants, such as carbon fluoride (CₓF_{y}), nitrogen (N₂), carbon dioxide (CO₂), argon (Ar), and a combination thereof. In some embodiments, the etchants can be in a form of a plasma. In some embodiments, etching dielectric layers 108 and 110 can include a combination of the dry and wet etching processes.

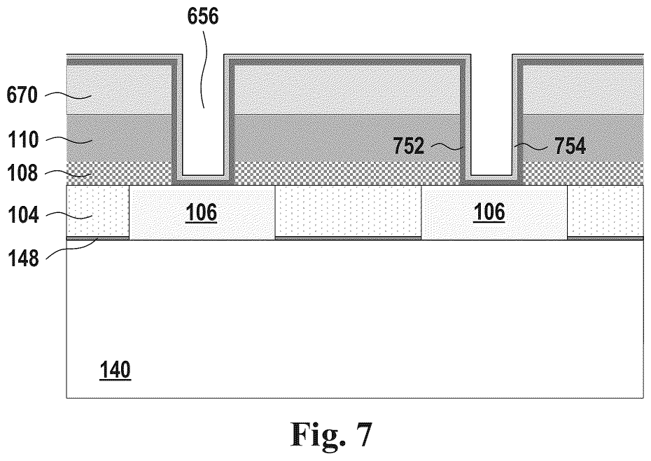

Referring to FIG. 3, method 300 can continue with operation 320 and the process of depositing a first barrier layer and a seed layer in the openings. For example, a barrier layer 752 and a seed layer 754 can be sequentially deposited over top surfaces of photoresist 670 as well as surfaces in openings 656, such as side surfaces of photoresist 670 and dielectric layers 110 and 108 and top surfaces of conductive line 106, as described with reference to FIG. 7. In some embodiments, depositing barrier layer 752 can include blanket depositing a layer of TaN or Ti. In some embodiments, after the deposition of barrier layer 752, seed layer 754 can be deposited by blanket depositing a layer of Cu. In some embodiments, barrier layer 752 and seed layer 754 can be deposited by a CVD process, an ALD process, a PECVD process, and/or a PVD process. In some embodiments, deposition parameters (e.g., the deposition time, the deposition rate, the pressure of the deposition chamber, the temperature of substrate 140, and/or the flowrates of the precursor gases) can be controlled during the deposition of barrier layer 752 and seed layer 754 to control their thicknesses.

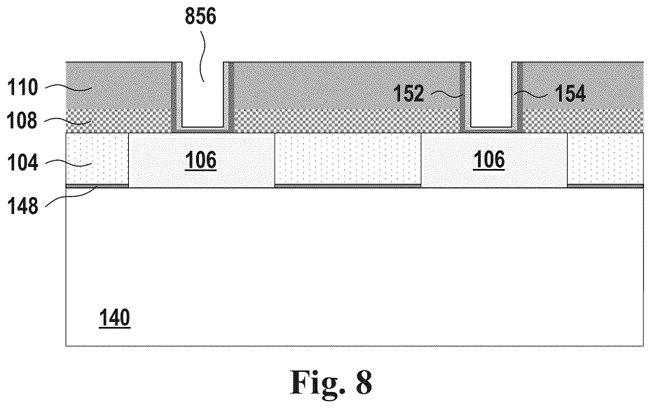

In some embodiments, after the deposition of barrier layer 752 and seed layer 754, operation 320 can further include a lift-off process to remove photoresist 670. The lift-off process can also remove portions of barrier layer 752 and seed layer 754 deposited on top and side surfaces of photoresist 670, as described with reference to FIG. 8. After the lift-off process, barrier layer 152 and seed layer 154 are left in openings 856. In some embodiments, the lift-off process can form the top surfaces of barrier layer 152 and seed layer 154 coplanar with the top surface of dielectric layer 110.

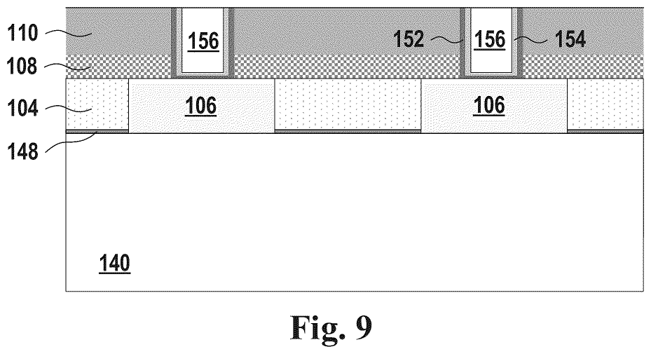

Referring to FIG. 3, method 300 can continue with operation 325 and the process of depositing a layer of conductive material in the opening. For example, conductive layer 156 can be formed by depositing a metal in openings 856, as described with reference to FIG. 9. In some embodiments, depositing the metal in openings 856 can include depositing Cu. For example, Cu can be deposited in openings 856 by an electrochemical plating (ECP) process. In some embodiments, seed layer 154 can facilitate the deposition of Cu in openings 856. During the ECP process, Cu can be deposited using an electrolyte, such as a mixture of copper sulfate and sulfuric acid. Deposition parameters, such as the deposition rate, the concentration of copper sulfate in the electrolyte, the current density applied in the ECP process, the plating time, and/or the temperature of the electrolyte, can be controlled to control the thickness of conductive layer 156. In some embodiments, the thickness of conductive layer 156 can be controlled such that conductive layer 156 is formed with its top surface coplanar with those of barrier layer 152, seed layer 154, and dielectric layer 110. In some embodiments, the thickness of conductive layer 156 can be controlled such that the maximal variance ΔT between thicknesses T0 and T=T1+T2+T3 as shown in FIG. 2 can be between about 0.01 μm and about 0.3 μm.

In some embodiments, operation 325 can further include a planarization process to improve the maximal variance ΔT. For example, a chemical mechanical polishing (CMP) process can be applied to form the coplanar top surfaces of dielectric layer 110, barrier layer 152, seed layer 154, and conductive layer 156, such that the maximal variance ΔT can be further improved to be between about 0.01 μm and about 0.1 μm. In some embodiments, the planarization of the top surfaces of dielectric layer 110, barrier layer 152, seed layer 154, and conductive layer 156 can promote the quality of structures subsequently fabricated on these top surfaces.

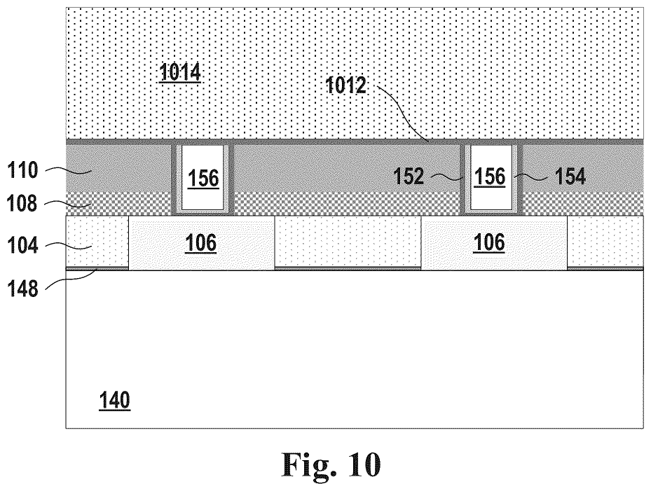

Referring to FIG. 3, method 300 can continue with operation 330 and the process of depositing a second barrier and a metal layer on the conductive layers and the dielectric layer. For example, as described with reference to FIG. 10, a barrier layer 1012 can be deposited on the top surfaces of dielectric layer 110, barrier layer 152, seed layer 154, and conductive layer 156, and a metal layer 1014 can be deposited on barrier layer 1012. In some embodiments, depositing barrier layer 1012 can include blanket depositing a layer of TaN or Ti on the top surfaces of dielectric layer 110, barrier layer 152, seed layer 154, and conductive layer 156 by a CVD process, an ALD process, a PECVD process, and/or a PVD process. In some embodiments, depositing metal layer 1014 can include blanket depositing a layer of metallic material (e.g., Al, Cu, W, Ru, Mo, Co, or a combination thereof) by a CVD process, an ALD process, a PECVD process, and/or a PVD process.

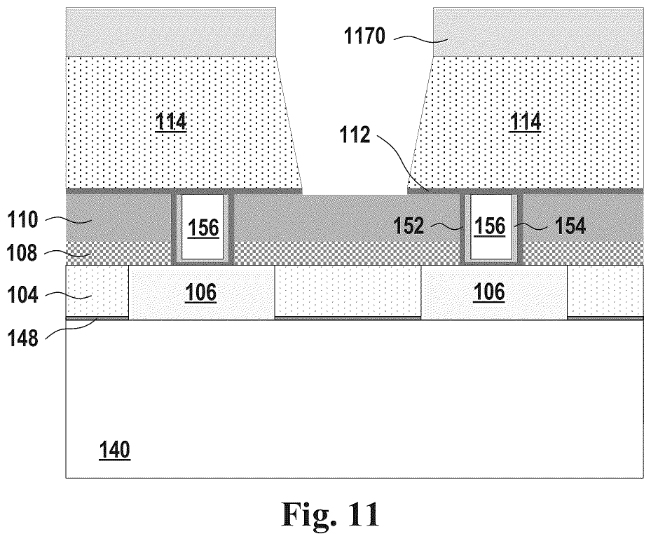

Referring to FIG. 3, method 300 can continue with operation 335 and the process of patterning the metal layer and the second barrier layer to form redistribution lines (RDLs). For example, a patterned photoresist 1170 can be formed on metal layer 1014, which is etched through according to the patterned photoresist 1170 to form RDLs 114, as described with reference to FIG. 11. Barrier layer 1012 can also be etched according to the patterned photoresist 1170 into barrier layers 112 underneath each of RDLs 114. In some embodiments, etching metal layer 1014 and barrier layer 1012 can include a dry etching process with etchants, such as carbon fluoride (CₓF_{y}), nitrogen (N₂), carbon dioxide (CO₂), argon (Ar), and a combination thereof. In some embodiments, the etchants can be in a form of a plasma. In some embodiments, etching metal layer 1014 and barrier layer 1012 can include a combination of the dry and wet etching processes. In some embodiments, photoresist 1170 can be patterned according to a mask based on the minimal distance L1 as shown in FIG. 1, such that after etching metal layer 1014, distance between RDLs 114 is greater than the minimal distance L1.

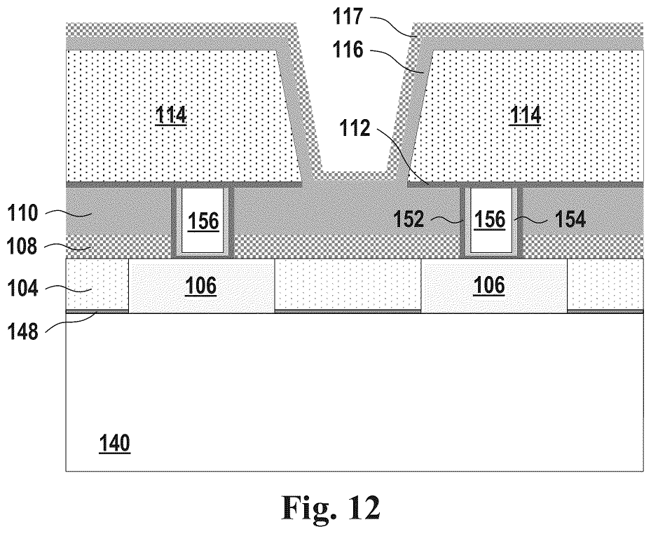

Referring to FIG. 3, method 300 can continue with operation 340 and the process of depositing a passivation layer over the RDLs. For example, passivation layer 116 can be deposited over top and side surfaces of RDLs 114, as described with reference to FIG. 12. In some embodiments, passivation layers 116 can also be deposited on side surfaces of barrier layer 112 and exposed top surfaces of dielectric layer 110. In some embodiments, depositing passivation layer 116 can include blanket depositing a layer of dielectric material (e.g., silicon oxide or silicon nitride) over exposed surfaces of the structure as shown in FIG. 11. In some embodiments, passivation layer 117 can be deposited over passivation layer 116, and can include blanket depositing a layer of dielectric material different from that of passivation layer 116. In some embodiments, passivation layers 116 and 117 can be deposited by a CVD process, an ALD process, a PECVD process, and/or a PVD process. In some embodiments, deposition parameters can be controlled to control deposition rates and thicknesses of passivation layers 116 and 117 according to the minimal distance L1 between RDLs 114, such that passivation layers 116 and 117 can form conformal coverage of the top and side surfaces of RDLs 114 without defects (such as voids or seams) especially in regions between RDLs 114.

Referring to FIG. 3, method 300 can continue with operation 345 and the process of forming RDL contacts through the passivation layer and in contact with the RDLs. For example, as described with reference to FIG. 1, contact structure 126 can be formed through passivation layers 116 and 117 and in contact with RDL 114. In some embodiments, forming contact structure 126 can include (i) forming polyimide layer 118 on passivation layer 117, (ii) patterning polyimide layer 118 to form openings through polyimide layer 118 and directly above RDLs 114 to expose a top surface of passivation layer 117, (iii) etching through passivation layers 117 and 116 according to the patterned polyimide layer 118, (iv) depositing UBM 120 in contact with the top surface of RDL 114, (v) depositing metal bump 122 on UBM 120, and (vi) depositing solder 124 on metal bump 122.

The embodiments described herein are directed to a structure including a conductive via connecting a redistribution line (RDL) and an interconnect structure and a method of forming the structure. The structure can include a conductive line in a substrate and a dielectric layer on the conductive line. The structure can further include the conductive via through the dielectric layer and in contact with the conductive line. The conductive via can include a first barrier layer on a side surface of the dielectric layer, a seed layer on the barrier layer, and a conductive layer surrounded by the seed layer. Top surfaces of the conductive via and the dielectric layer can be substantially coplanar. The structure can further include a second barrier layer on the conductive via and the dielectric layer and a redistribution line (RDL) on the second barrier layer. Due to the substantially coplanar top surfaces of the conductive via and the dielectric layer, a top surface of the RDL can be substantially even and smooth and free from irregular concave shapes. The structure can further include a passivation layer in contact with the top surface of the RDL. Being formed on the substantially even and smooth top surface, the passivation layer can have reliable thermal and mechanical properties.

In some embodiments, a method includes providing a substrate having a conductive line and a dielectric layer on the conductive line and etching an opening in the dielectric layer to expose the conductive line. The method further includes depositing a first barrier layer on side surfaces of the opening, depositing a seed layer on the first barrier layer, and depositing a first metal in the opening to form a conductive via having a top surface coplanar with a top surface of the dielectric layer. The method further includes depositing a second barrier layer on the top surfaces of the conductive via and the dielectric layer and depositing a second metal on the second barrier layer to form a redistribution line (RDL) having a top surface parallel to the top surface of the dielectric layer.

In some embodiments, a method includes forming first and second conductive lines on a substrate and forming a dielectric layer on the first and second conductive lines. The method further includes forming first and second conductive vias through the dielectric layer and in contact with the first and second conductive lines, respectively. Forming the first and second conductive vias includes etching first and second openings through the dielectric layer to expose the first and second conductive lines, respectively. Forming the first and second conductive vias includes depositing first and second barrier layers in the first and second openings, respectively. Forming the first and second conductive vias includes depositing first and second conductive layers on the first and second barrier layers, respectively. Top surfaces of the first and second conductive layers are formed to be substantially coplanar with a top surface of the dielectric layer. The method further includes forming first and second redistribution lines (RDL) in contact with the top surfaces of the first and second conductive vias, respectively. Top surfaces of the first and second RDLs are formed to be substantially flat.

In some embodiments, a structure includes a conductive line on a substrate and a dielectric layer on the conductive line. The structure further includes a conductive via through the dielectric layer and in contact with the conductive line. The conductive via includes a first barrier layer on a side surface of the dielectric layer, a seed layer on the barrier layer, and a conductive layer surrounded by the seed layer. The conductive layer includes a first metal. The structure further includes a second barrier layer on the conductive via and the dielectric layer and a redistribution line (RDL) on the second barrier layer. The RDL includes a second metal different from the first metal. A top surface of the RDL includes a first portion above the conductive via and a second portion above the dielectric layer. A first vertical distance between the first portion and the conductive line is substantially the same as a second vertical distance between the second portion and the conductive line.

It is to be appreciated that the Detailed Description section, and not the Abstract of the Disclosure section, is intended to be used to interpret the claims. The Abstract of the Disclosure section may set forth one or more but not all possible embodiments of the present disclosure as contemplated by the inventor(s), and thus, are not intended to limit the subjoined claims in any way.

The foregoing disclosure outlines features of several embodiments so that those skilled in the art may better understand the aspects of the present disclosure. Those skilled in the art will appreciate that they may readily use the present disclosure as a basis for designing or modifying other processes and structures for carrying out the same purposes and/or achieving the same advantages of the embodiments introduced herein. Those skilled in the art will also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
providing a substrate having a conductive line and a dielectric layer on the conductive line;
etching an opening in the dielectric layer to expose the conductive line;
depositing a first barrier layer on side surfaces of the opening;
depositing a seed layer on the first barrier layer;
depositing a first metal in the opening to form a conductive via having a top surface coplanar with a top surface of the dielectric layer;
depositing a second barrier layer on the top surfaces of the conductive via and the dielectric layer; and
depositing a second metal on the second barrier layer to form a redistribution line (RDL) having a top surface parallel to the top surface of the dielectric layer.

2. The method of claim 1, wherein the first and second metals are different.

3. The method of claim 2, wherein the first and second metals are copper and aluminum, respectively.

4. The method of claim 1, wherein depositing the first metal comprises depositing the first metal on the seed layer by performing an electrochemical plating process.

5. The method of claim 4, wherein depositing the first metal further comprises controlling a thickness of the conductive via such that a difference between a thickness of the conductive via and a thickness of the dielectric layer is less than about 0.3 μm.

6. The method of claim 5, wherein depositing the first metal further comprises performing a chemical mechanical polishing process so the difference is between about 0.01 μm and about 0.1 μm.

7. The method of claim 1, wherein:
depositing the first barrier layer comprises controlling a thickness of the first barrier layer to be between about 30 nm and about 100 nm; and
depositing the seed layer comprises controlling a thickness of the seed layer to be between about 30 nm and about 200 nm.

8. A method, comprising:
forming first and second conductive lines on a substrate;
forming a dielectric layer on the first and second conductive lines;
forming first and second conductive vias through the dielectric layer and in contact with the first and second conductive lines, respectively, wherein forming the first and second conductive vias comprises:
etching first and second openings through the dielectric layer to expose the first and second conductive lines, respectively;
depositing first and second barrier layers in the first and second openings, respectively; and
depositing first and second conductive layers on the first and second barrier layers, respectively, wherein top surfaces of the first and second conductive layers are substantially coplanar with a top surface of the dielectric layer; and
forming first and second redistribution lines (RDL) on the top surfaces of the first and second conductive vias, respectively, wherein top surfaces of the first and second RDLs are substantially flat.

9. The method of claim 8, wherein forming the first and second RDLs comprises controlling a distance between the first and second RDLs to be between about 0.5 μm and about 2 μm.

10. The method of claim 9, wherein the minimal distance is about 1 μm.

11. The method of claim 8, wherein top surfaces of the first and second RDLs are substantially coplanar with each other.

12. The method of claim 8, further comprising forming third and fourth barrier layers under the first and second RDLs, respectively, wherein the first and third barrier layers enclose the first conductive layer, and wherein the second and fourth barrier layers enclose the second conductive layer.

13. The method of claim 12, wherein a first interface between the third barrier layer and the first RDL and a second interface between the fourth barrier layer and the second RDL are substantially coplanar.

14. The method of claim 8, further comprising depositing a passivation layer over the first and second RDLs and in contact with the dielectric layer.

15. A structure, comprising:
a conductive line on a substrate;
a dielectric layer on the conductive line;
a conductive via through the dielectric layer and in contact with the conductive line, wherein the conductive via comprises:
a first barrier layer on a side surface of the dielectric layer;
a seed layer on the barrier layer; and
a conductive layer surrounded by the seed layer and comprising a first metal;
a second barrier layer on the conductive via and the dielectric layer; and
a redistribution line (RDL) on the second barrier layer and comprising a second metal different from the first metal, wherein a top surface of the RDL comprises a first portion above the conductive via and a second portion above the dielectric layer, and wherein a first vertical distance between the first portion and the conductive line is substantially the same as a second vertical distance between the second portion and the conductive line.

16. The structure of claim 15, wherein a first thickness of the conductive via is substantially the same as a second thickness of the dielectric layer.

17. The structure of claim 15, wherein a difference between the first and second vertical distances is less than about 0.01 μm.

18. The structure of claim 15, wherein the conductive layer and the seed layer are enclosed by the first and second barrier layers.

19. The structure of claim 15, further comprising a passivation layer on the RDL and comprising a portion directly above the conductive via and the dielectric layer, wherein a top surface of the portion is parallel to a top surface of the conductive line.

20. The structure of claim 15, wherein an interface between the RDL and the second barrier layer and directly above the conductive via and the dielectric layer is parallel to a top surface of the conductive line.
